(19) United States
(12) Patent Application Publication
(10) Pub. No.: US 2004/0124494 A1
(43) Pub. Date: Jul. 1, 2004

(54) Process for forming trenches with oblique profile and rounded top corners

(75) Inventors: Francesco Ciovacco, Milano (IT); Chiara Savardi, Brescia (IT); Roberto Colombo, Lentate Sul Seveso (IT)

Correspondence Address: GRAYBEAL JACKSON HALEY LLP, Suite 350, 155-108th Avenue N.E., Bellevue, WA, 98004-5973, US

(73) Assignee: STMicroelectronics S.r.I.

(21) Appl. No.: 10/608,855

(22) Filed: Jun. 27, 2003

(30) Foreign Application Priority Data
Jun. 28, 2002 (EP) 02425428.6

(51) Int. Cl. H01L 29/00

(52) U.S. Cl. 257/510; 257/499

(57) ABSTRACT

A process for forming trenches with an oblique profile and rounded top corners, including the steps of: in a semiconductor wafer, through a first polymerizing etch, forming depressions delimited by rounded top corners; and through a second polymerizing etch, opening trenches at the depressions. The second polymerizing etch is made in variable plasma conditions, so that the trenches have oblique walls with a constant slope.

### PRIORITY CLAIM

This application claims priority from European patent application No. 02425428.6, filed Jun. 28, 2002, which is incorporated herein by reference.

### TECHNICAL FIELD

The present invention relates generally to a process for forming trenches with oblique profile and rounded top corners.

### BACKGROUND

As is known, in microelectronics there is an ever-increasing need to reduce the overall dimensions of integrated circuits. Clearly, to achieve this aim, it is necessary, on the one hand, to optimize the number of electronic components to be made and, on the other, to minimize the size of the components and, in general, of all the structures that cooperate in the operation of the integrated circuit.

The reduction of the size causes, however, difficulties, for example, in forming insulating structures that separate adjacent active areas, and it is therefore necessary to adopt particular solutions.

For example, so-called shallow-trench isolation (STI) structures are compatible with the use of technologies that enable the fabrication of active devices of length smaller than 0.25 μm. To form the insulating structures, in a wafer of semiconductor material a trench of preset width and depth is initially opened; then, the trench is filled with silicon oxide or with another dielectric material. The trench is normally dug by dry plasma etching, which is markedly anisotropic. The walls of the trench can in some cases be vertical, but frequently the geometrical and electrical characteristics of the circuits require the trench to have an oblique profile and the walls to be inclined, for example by an angle of between 650 and 850 (tapered trench). This solution makes it possible, for example, to prevent the electric field lines from crowding near over-pronounced corners, so creating potentially dangerous situations.

In order to improve the insulating structures of an STI type, it has been proposed to provide the trenches with rounded top corners, using the top-corner rounding (TCR) technique. This technique chiefly provides two advantages: first, the space available for forming active areas increases and, second, the likelihood of the subsequent processing steps causing crystallographic defects is reduced.

A first known process for forming trenches provided with rounded top corners will be illustrated with reference to FIGS. 1-6. According to this process, a semiconductor wafer 1 is initially coated with a pad oxide layer 2 and with a stop layer 3 of silicon nitride having openings 4 obtained with conventional lithographic techniques (FIG. 1). The stop layer 3 is to be used for subsequent steps of planarization of the wafer 1. Then, a thick oxide layer 5 is deposited so as to coat the stop layer 3 (FIG. 2) and is then defined so as to form spacers 6 inside the openings 4 (FIG. 3). In greater detail, the spacers 6 occupy peripheral portions of the openings 4, leaving central portions uncovered. By anisotropic plasma etching, a trench 7 with a preset profile is then opened (FIG. 4) and, with a wet etch, the spacers 6 and portions of the pad oxide layer 2 inside the openings 4 are then removed (FIG. 5). Now, referring to FIG. 6, the trench 7 is upwardly delimited by top corners 8 having edges 9. By a further dry etch, the edges 9 are tapered, so as to obtain rounded top corners 8′.

Referring again to FIGS. 5-6, the described process is not, however, free from limitations. First, the dry etch for rounding off the edges 9 inevitably also involves the walls of the trench 7, the profile of which is modified in an uncontrollable way. This undesired effect is disadvantageous, since the electrical properties of an insulating structure depend, in general, also upon its shape. Clearly, it is difficult, if not impossible, to foresee accurately the electrical interactions between the insulating structure obtainable by filling in the trench 7 and the devices that are to be made in the wafer 1. These interactions can render the behavior of the devices integrated in the wafer significantly different from the design, both as regards performance and as regards safety margins for protection from any possible failure. In addition, numerous processing steps are necessary, in particular, a greater number of alternate plasma and wet etching steps. Consequently, the method is costly and complex to be implemented, and the risk of generating crystallographic defects is not satisfactorily small. Instead, on account of the high number and of the type of operations to be performed, the wafer must be handled and displaced a number of times between different machines: the wafer thus remains exposed to dust and other impurities that can cause defects or damage of varying degree.

A different process, illustrated with reference to FIGS. 7-10, provides forming a pad oxide layer 11 and a stop layer 12 on top of a wafer 10, as already described. In particular, the stop layer 12 is defined using a resist mask 13. Then (FIG. 8), uncovered portions of the pad oxide layer 11 and portions of silicon immediately underneath are removed through an anisotropic etch with inclined profile, in particular a polymerizing dry etch. As is known, this type of etching is performed in particular conditions, whereby, simultaneously with removing material from the wafer 1, the compounds present in the plasma are microdeposited. On the vertical or markedly inclined walls, the rate of microdeposition is higher than the rate of etching and consequently a protective polymeric film 14 progressively grows around the portions with high constant slope. Starting from the periphery, the horizontal surface exposed to etching gradually reduces over time; in this way, rounded top corners 15 are obtained, as shown in FIG. 8. Finally, a trench 16 is opened through a further dry anisotropic etch (FIG. 9), and the resist mask 13 and the polymeric film 14 are removed (FIG. 10a).

The process described above, however, has a considerable limitation, in so far as it does not enable trenches with an oblique profile to be formed, but only ones with vertical profile. To obtain an oblique profile, in fact, it is necessary to perform a further polymerizing dry etch, using a polymer that is very different from the previous one. In addition, the trench is opened before removing the polymeric film formed during the first dry etch, which is thus still present. In practice, the polymeric film affects the evolution of the second dry etch, inducing different rates of polymerization according to the depth reached inside the wafer 10. In greater detail, during the second dry etch a second polymeric film 17 is formed, which, however, does not grow in a regular way: at the start of the process and in the proximity of the polymeric film 14, the growth of the second polymeric film 17 is more rapid and slows down as the trench 16′ is dug. In practice, then, a crowned, substantially cusp-shaped, profile is obtained, as shown in FIG. 10b. The cusp-shaped profile is not satisfactory, both because it requires the devices to be designed taking into account complex phenomena, due precisely to the constant non-constant slope of the walls of the trench 16′, and, above all, because it causes various problems in the subsequent processing steps. In particular, the filling of the trench 16′ is problematical and thus is frequently imperfect; in the thermal treatment, the portions of the wafer 10′ surrounding the trench 16′ are subjected to extremely strong mechanical stresses; in addition, crystallographic defects may be formed, especially on the bottom of the trench 16′.

Still referring to FIGS. 7-10b, alternatively, it is possible to remove the polymeric film 14 formed during the first polymerizing etch before performing the second etch. However, the complete removal of the film grown during a polymerizing etch is problematical and requires a wet washing of the wafer, which, however, causes complete removal of the residual resist. The subsequent etches would thus have a very limited polymerizing power (the polymer comes, in fact, to a great extent from the products of etching of the photoresist), preventing in practice the obtainment of the desired oblique profile. In addition, this solution involves picking up the wafer, setting it in a different machine, carrying out washing, and re-positioning of the wafer to carry out the second plasma etch. All these steps must evidently be repeated to remove the films 14 and 17 separately, thus rendering the fabrication process excessively complex.

Therefore, a need has arisen for a process for forming insulating structures that is free from the drawbacks described above.

### SUMMARY

According to an embodiment of the present invention a process is provided for forming insulating structures with an oblique profile and rounded top corners.

### BRIEF DESCRIPTION OF THE DRAWINGS

For a better understanding of the invention, some embodiments thereof are now described, purely by way of non-limiting examples and with reference to the attached drawings, wherein:

FIGS. 1-6 are cross-sections through a semiconductor wafer in successive processing steps, according to a known process;

FIGS. 7-10b are cross-sections through semiconductor wafers in successive processing steps, according to a different known process;

FIGS. 11-15 are cross-sections through a semiconductor wafer in successive processing steps of the process according to an embodiment of the present invention;

FIG. 16 is a schematic view of an apparatus used in one step of the process according to an embodiment of the present invention;

FIG. 17 is the plot of a quantity regarding the present process according to an embodiment of the present invention;

FIGS. 18-20 are cross-sections of the wafer of FIGS. 11-15, in subsequent processing steps according to an embodiment of the present invention; and

FIGS. 21-23 are plots of quantities regarding, respectively, a second, a third, and a fourth embodiment of the process according to the present invention.

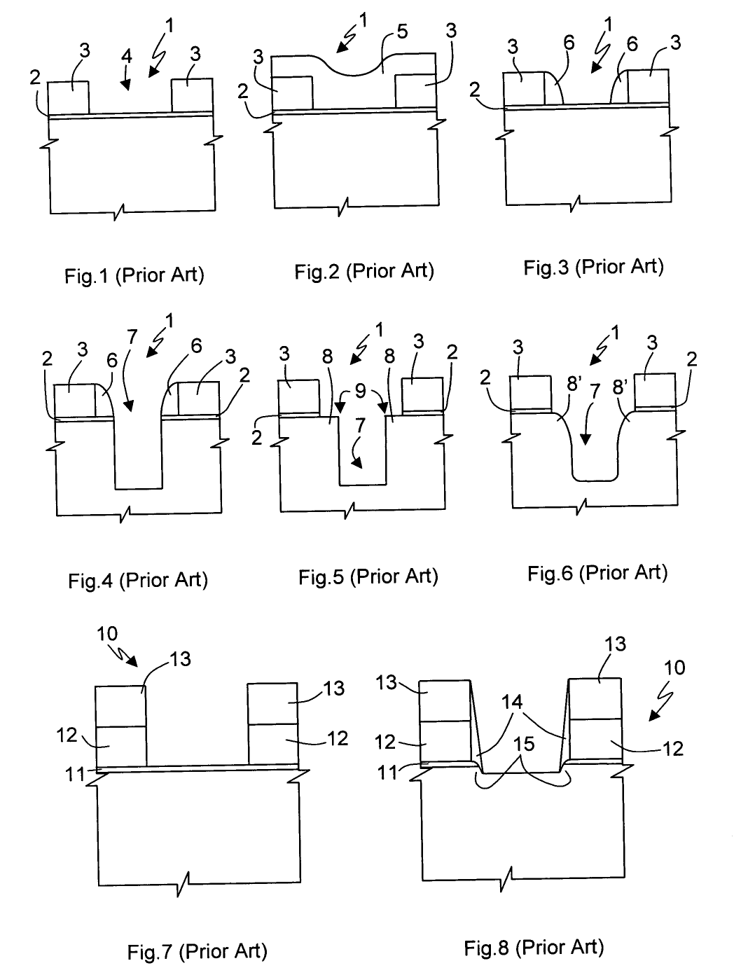

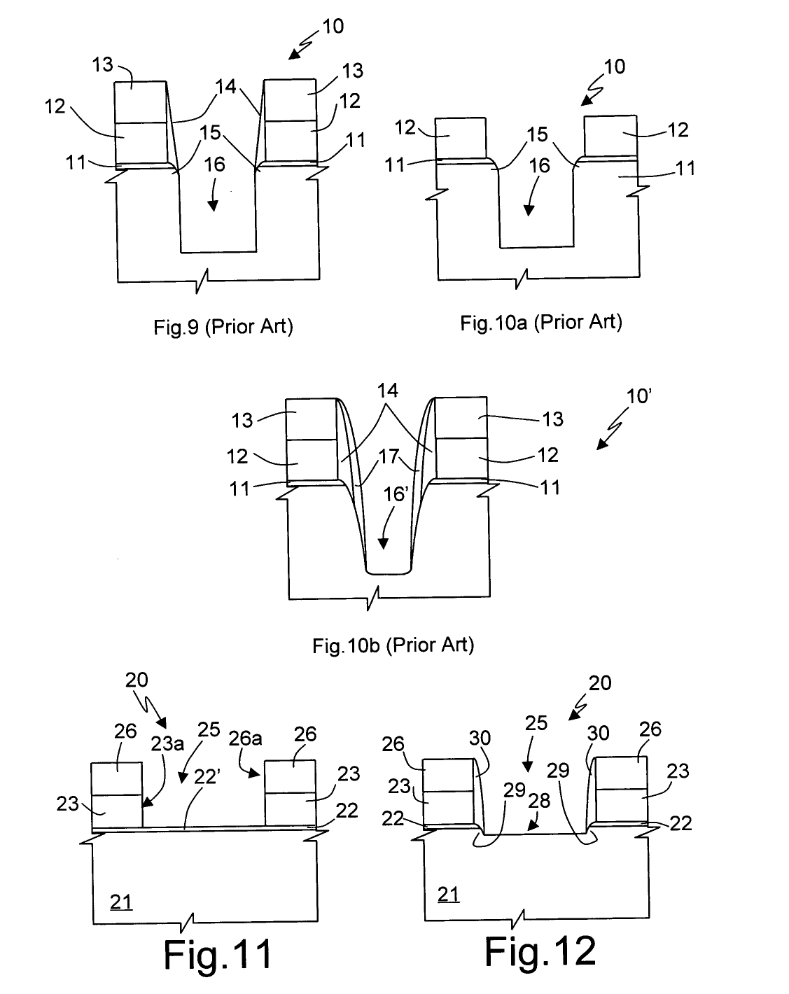

### DETAILED DESCRIPTION

With reference to FIGS. 11-20, a wafer 20 of semiconductor material, for example monocrystalline silicon, comprises a substrate 21, on which a pad oxide layer 22 is initially grown. On top of the pad oxide layer 22 a stop layer 23 is then formed, which is to be used for subsequent planarization of the wafer 20. The stop layer 23 has openings 25 uncovering portions 22′ of the pad oxide layer 22; in particular the portions 22′ rise above regions of the substrate 21 that are subsequently to be etched. The stop layer 23 is formed using a resist mask 26, which is deposited and then defined photolithographically.

Then, a first dry polymerizing etch is carried out, as shown in FIG. 12. The polymerizing etch is a plasma etch, preferably, but not mandatorily, a CHF₃- or CH₂F₂-based etch. In detail, in this step, the portions 22′ of the pad oxide layer 22 are removed, and the underlying silicon is slightly dug so as to form depressions 28. During the polymerizing etch, on the surface 23a of the hard mask 23 and on the surface 26a of the resist mask 26 delimiting the openings 25 a first polymeric film 30 is formed, which gradually grows in thickness towards the inside of the openings 25. As the thickness of the first polymerizing film 30 increases, first the exposed surface of the pad oxide layer 22 and next that of the substrate 21 decreases, starting from the periphery. Consequently, with the passage of time the etch involves an increasingly restricted central area, which is dug more deeply at the bottom than at the peripheral areas. In this way, rounded top corners 29 are formed, which delimit the depressions 28.

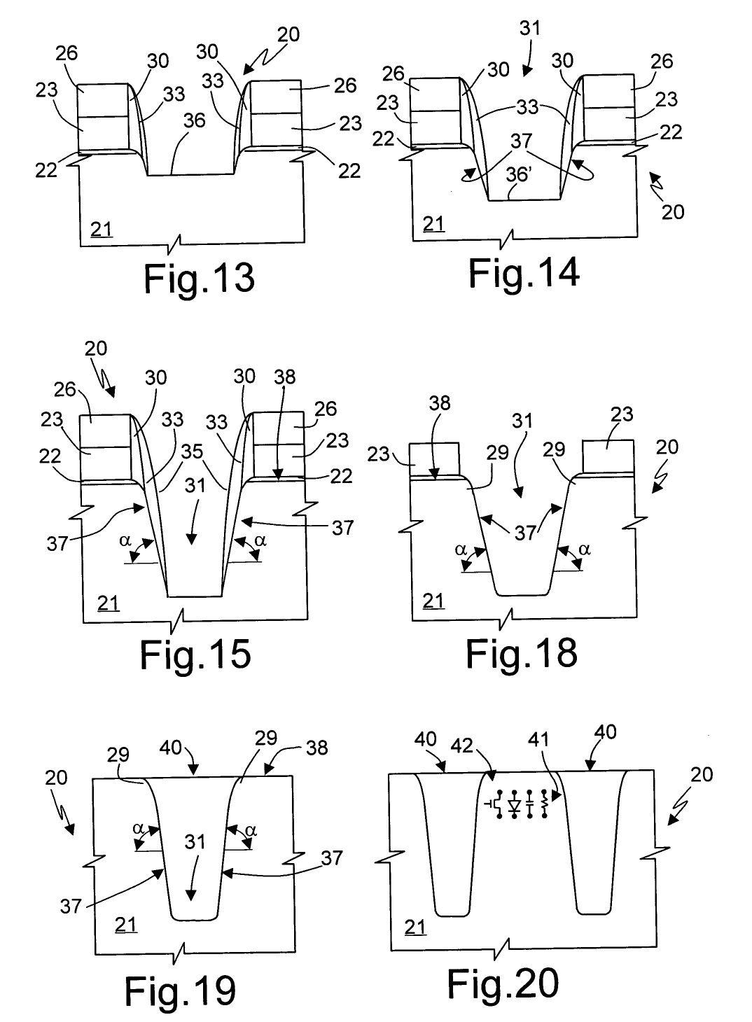

A second dry polymerizing etch is then performed to open a trench 31 (FIGS. 13-15). The second polymerizing etch is a markedly anisotropic plasma etch, preferably, but not mandatorily, HBr- and O₂-based; in addition, the etch can be made in presence of Cl₂ and N₂. The second polymerizing etch is performed in variable plasma conditions.

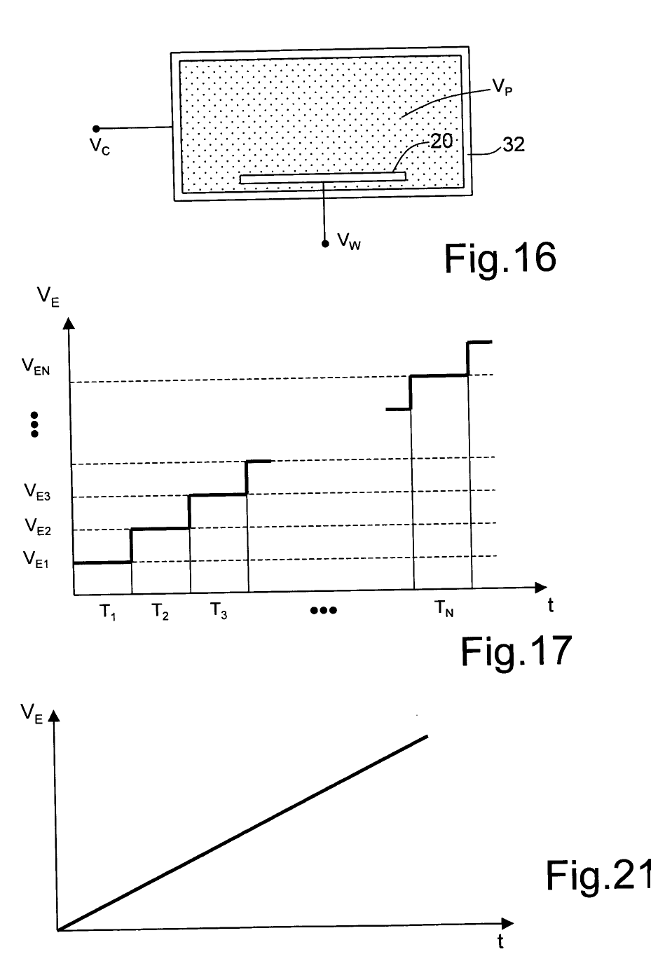

In greater detail, plasma etching is performed by placing the wafer 20 in an etching chamber 32, in which a known mixture of gases flows in predetermined conditions of temperature, pressure and flow (FIG. 16). In addition, the etching chamber 32 is set at a chamber voltage V_{C}, while the wafer 20 is kept at a wafer voltage V_{W}. The plasma, coming into contact with the etching chamber 32, reaches a plasma voltage V_{P} higher by a known amount than the chamber voltage V_{C}. Consequently, an etching voltage V_{E}=V_{P}−V_{W} is present between the exposed surface of the wafer 20 (more specifically, of the substrate 21) and the plasma; in addition, the etching voltage V_{E} is controllable through the wafer voltage V_{W}. The rate of removal of the silicon and the rate of microdeposition of the polymeric material of the plasma are affected by various parameters, among which the etching voltage V_{E}. In particular, all other conditions being equal, the rate of microdeposition increases as the absolute value of the etching voltage V_{E} increases.

Then, during the second polymerizing etch, a second polymeric film 33 is formed, which grows at a rate that depends upon the etching voltage V_{E}. According to the invention, the etching voltage V_{E} is varied during the second polymerizing etch so as to control the growth of the second polymeric film 33 and thus the slope of the walls 35 of the trench 31. In greater detail, the second polymerizing etch is performed in discrete steps and comprises a number N of steps performed in succession. As shown in FIG. 17, associated with the etching steps are respective durations T₁, T₂, . . . , T_{N} and respective increasing values V_{E1}, V_{E2}, . . . , V_{EN} of the etching voltage V_{E}. For example, the second polymerizing etch comprises three steps, each having a duration of 30 s. Furthermore, for each step the value of the etching voltage V_{E} is obtained by keeping the chamber voltage V_{C} constant (for example at 0 V) and imposing values of the wafer voltage V_{W} of 10 V, 20 V and 30 V, respectively. Thereby, a discrete-ramp etching voltage V_{E} is supplied. The etching steps are moreover performed one after the other, in rapid succession, substantially without interruptions.

In this way, the variations in the growth rate of the second polymerizing film 33 caused by the presence of the first polymerizing film 30 are compensated, in particular near the exposed surface 36 of the substrate 21. In an initial step of the second polymerizing etch (FIG. 13), the growth of the second polymeric film is rapid because, in addition to the effect due to the etching voltage V_{E}, the presence of the first polymeric film 30 has a significant effect. In fact, the first polymeric film 30 is initially contiguous to the exposed surface 36 that is etched.

In a subsequent step (FIG. 14), after a first amount of silicon has been removed and the trench 31 has started to form, the exposed surface 36′ is found at a greater depth in the substrate 21. Given that the distance from the first polymeric film 30 has increased, the influence of the latter on the rate of growth of the second polymeric film 33 near the exposed surface 36′ is smaller, but is compensated for by the increment imposed on the etching voltage V_{E}. In practice, then, the portion of the substrate 21 exposed to etching continues to decrease gradually and in a way correlated to the removal rate of the silicon; the slope of the walls 37 that delimit the trench 31 is thus kept constant.

In the subsequent etching steps, the etching voltage V_{E} is varied as already explained with reference to FIG. 17, so that the variations in the microdeposition rate of polymeric material and in the removal rate of silicon will make up for the different effect caused by the first polymeric film 30.

FIG. 15 shows the wafer 20 at the end of the second polymerizing etch: it is possible to identify the trench 31, delimited by the walls 37 with a constant slope a and the first and the second polymeric films 30, 33. In particular, the walls 37 form this angle α with respect to a surface parallel to a face 38 of the substrate 21. Preferably, but not mandatorily, the angle α is between 65° and 85° and, for example, is 80°.

After the second polymerizing etch, the first and the second polymeric films 30, 33 and the resist mask 26 are removed simultaneously with a single step of wet washing (FIG. 18). By chemical-vapor deposition (CVD), the trench 31 is then completely filled with a dielectric material, preferably, but not mandatorily, silicon oxide, so as to form an insulating structure 40 extending in the substrate 21 for the entire depth of the trench 31 (FIG. 19). Excess portions of silicon oxide, the stop layer 23, and the pad oxide layer 22 are then removed after planarization of the wafer 20. In one embodiment of the invention, the processing of the wafer 20 is then completed with standard steps for forming integrated circuits 41, represented schematically in FIG. 20 by the symbols of active and passive electronic components. In particular, the integrated circuits 41 are made inside active areas 42 of the wafer 20 delimited by adjacent insulating structures 40.

In a second embodiment of the invention, the etching voltage V_{E} is varied continuously according to a linear ramp, as shown in FIG. 21. Also in this embodiment, the wafer voltage V_{W} is controlled so as to obtain the desired etching voltage V_{E}.

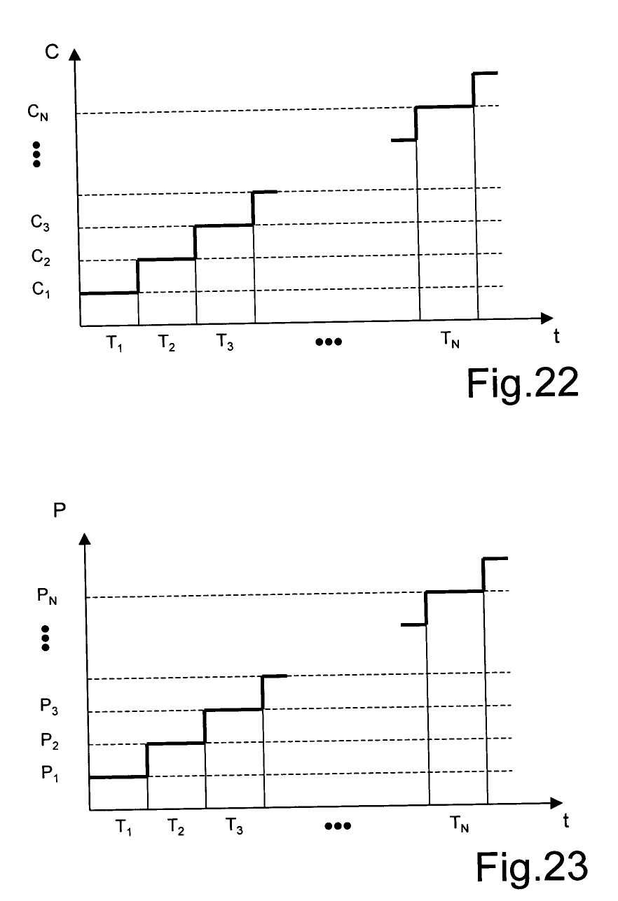

A third embodiment of the invention provides for varying the composition of the plasma used during the second polymerizing etch. In greater detail, at least two gases are present in the plasma: a first gas, for example HBr or Cl₂, is used for etching the substrate 21, while a second gas, for example O₂, HeO₂ or N₂, brings about polymerization and microdeposition of polymeric material. In order to control the polymerization rate, the concentration C of the polymerizing gas present in the mixture is varied. In particular, the concentration C is increased according to a discrete-ramp pattern, as illustrated in FIG. 22.

In a fourth embodiment of the invention, during the second polymerizing etch the pressure P of the plasma is modified, also in this case according to a discrete-ramp pattern (see FIG. 23).

The process described is advantageous mainly because it enables insulating structures to be made with inclined walls having a constant slope and at the same time to be provided with rounded top corners. It is therefore possible to exploit the advantages of the TCR technique also in the numerous cases where it is necessary to dig trenches with an oblique profile. In particular, it is possible to define active areas of high quality and to reduce the parasitic effects within the active areas. In addition, the use of the TCR technique for digging trenches reduces the risk of any crystallographic defects being generated in subsequent processing steps, especially during thermal treatment. In practice, then, both the yield of the process and the quality of the devices that can be made in the active areas improve considerably.

In addition, the process is carried out in an extremely simple way, in so far as the execution of a low number of steps is required, which are moreover very common in microelectronics. Consequently, the overall cost of the process according to the above-described embodiments of the invention is very contained.

Finally, it is evident that modifications and variations may be made to what is described herein, without departing from the scope of the present invention.

For example, during the second polymerizing etch, it is possible to vary the etching voltage in a way different from what has been described herein. In particular, the etching voltage may present a parabolic curve, either a continuous one or a discrete one, or even of some other type. Furthermore, in the case of an etching voltage that varies according to a staircase function, the increments of the etching voltage might not be uniform.

Likewise the various steps of the second polymerizing etch may also have different durations.

What is claimed is:

1. A process for forming trenches with an oblique profile and rounded top corners, comprising the steps of:
through a first polymerizing etch, forming in a semiconductor wafer depressions delimited by rounded top corners; and
through a second polymerizing etch, opening trenches at said depressions;
characterized in that said second polymerizing etch is performed in variable plasma conditions.

2. The process according to claim 1, characterized in that said step of forming said second polymerizing etch comprises varying an etching voltage between said plasma and said wafer.

3. The process according to claim 2, characterized in that said step of varying comprises increasing said etching voltage.

4. The process according to claim 2, characterized in that said etching voltage is a discrete-ramp voltage.

5. The process according to claim 4, characterized in that said etching voltage has steps of constant duration.

6. The process according to claim 5, characterized in that said constant duration is 30 s.

7. The process according to claim 2, characterized in that said etching voltage is a linear-ramp voltage.

8. The process according to claim 2, characterized in that said step of varying said etching voltage comprises:
placing said wafer in an etching chamber;
supplying to said etching chamber a constant chamber voltage; and
supplying to said wafer a variable wafer voltage.

9. The process according to claim 1, characterized in that said second polymerizing etch is an HBr- and O₂-based etch.

10. The process according to claim 9, characterized in that said second polymerizing etch is made in the presence of Cl₂ and N₂.

11. The process according to claim 1, characterized in that said first polymerizing etch is made using a substance chosen in the group comprising CHF₃, CH₂F₂.

12. The process according to claim 1, characterized in that said step of forming said second polymerizing etch comprises increasing a concentration of a polymerizing species present in said plasma.

13. The process according to claim 1, characterized in that said step of forming said second polymerizing etch comprises increasing a pressure of said plasma.

14. The process according to claim 1, characterized in that said step of forming a first polymerizing etch and said step of forming a second polymerizing etch are performed using a masking structure.

15. The process according to claim 1, characterized in that it comprises the step of filling said trench with a dielectric material.

16. A semiconductor wafer comprising active areas and trenches defining said active areas; characterized in that said trenches have rounded top corners and are delimited by oblique walls having constant slope.

17. The wafer according to claim 16, characterized in that said constant slope is between 65° and 850.

18. The wafer according to claim 16, characterized in that said trenches are filled with dielectric material, thereby forming insulating structures.

19. A method comprising:
forming a trench in an unmasked area of a substrate, the trench having inclined walls with a substantially constant slope and with rounded top corners; and
filling the trench with a dielectric material.

20. The method of claim 19 wherein forming the trench further comprises:
performing a first plasma etch; and
performing a second plasma etch.

21. The method of claim 20 wherein the first plasma etch further comprises:
forming a depression in the unmasked area of the substrate; and
forming a first polymeric film on the walls defined by the depression and a stop layer under a resist layer.

22. The method of claim 20 wherein the first plasma etch further comprises etching with a CHF₃ based plasma.

23. The method of claim 20 wherein the second plasma etch further comprises etching with a variable anisotropic plasma.

24. The method of claim 20 wherein the second plasma etch further comprises:
placing a wafer in a chamber;
filling the chamber with a plasma mixture of gases;
setting the temperature, pressure and gas flow;
setting a chamber voltage;
setting a series wafer voltages;
creating a series of etching voltages between the substrate and the plasma;
removing portions of the substrate by parts in series; and
depositing a second polymeric film on the walls by parts in series.

25. The method of claim 24 wherein the plasma mixture of gases further comprises mixing hydrogen bromide and oxygen.

26. The method of claim 24 wherein the plasma mixture of gases further comprises mixing chlorine and nitrogen.

27. The method of claim 24 wherein a rate of depositing the second polymeric film increases as the absolute value of the etching voltages increase.

28. The method of claim 24 wherein depositing the second polymeric film further comprises controlling the growth of the walls of the trench by the series of etching voltages.

29. The method of claim 24 wherein creating a series of wafer voltages further comprises:
setting the wafer voltage to 10 volts for a first thirty seconds;
setting the wafer voltage to 20 volts for a second subsequent thirty seconds; and
setting the wafer voltage to 30 volts for a third subsequent thirty seconds.

30. The method of claim 24 wherein removing portions of the wafer by parts in series further comprises:
exposing decreasing portions of the wafer; and
keeping a slope of the walls of the trench substantially constant.

31. The method of claim 30 wherein the slope the walls is at an angle between sixty-five and eighty-five degrees to a vertical.

32. The method of claim 19 wherein filling the trench with a dielectric material further comprises chemical-vapour deposition.

33. The method of claim 32, further comprising depositing silicon oxide.

34. The method of claim 24 wherein creating a series of etching voltages further comprises continuously varying a voltage in a linear manner.

35. The method of claim 24 wherein setting the gas flow further comprises:
etching the wafer with a first gas;
depositing a second polymeric film with a second gas;
varying the concentration of the second gas; and
controlling the rate of polymerization.

36. The method of claim 35, further comprising:
etching the wafer with hydrogen bromide; and
depositing the second polymeric film with helium oxide.

37. The method of claim 35, further comprising:
etching the wafer with hydrogen bromide; and
depositing the second polymeric film with oxygen.

38. The method of claim 35, further comprising:
etching the wafer with chlorine; and
depositing the second polymeric film with nitrogen.

39. The method of claim 35, further comprising varying the concentration of the second gas according to a discrete-ramp pattern.

40. The method of claim 24 wherein setting the pressure further comprises varying the pressure according to a discrete-ramp pattern during the second plasma etch.

41. The method of claim 24 wherein creating a series of etching voltages further comprises a non-uniform voltage step function.

42. The method of claim 24 wherein creating a series of etching voltages further comprises a discrete parabolic voltage function.

43. The method of claim 24 wherein creating a series of etching voltages further comprises a continuous parabolic voltage function.

44. The method of claim 24 wherein the steps have different durations.

45. A method for forming trenches with an oblique profile and rounded top corners in a wafer comprising:
forming depressions delimited by rounded top corners in a wafer with a first polymerizing etch; and
forming trenches at the depressions with a varying plasma polymerizing etch.

46. The method of claim 45 wherein forming trenches further comprises varying an etching voltage between a plasma and the wafer.

47. The method of claim 45 wherein varying an etching voltage further comprises increasing the etching voltage.

48. The method of claim 47 wherein increasing the etching voltage further comprises a discrete-ramp voltage function.

49. The method of claim 48 wherein the discrete-ramp voltage function further comprises steps of constant duration.

50. A micro-electric insulating structure, comprising:
a trench in a substrate with inclined walls having a substantially constant slope and with rounded top corners; and
a dielectric material disposed in the trench.

51. The structure of claim 50 wherein the substantially constant slope is between sixty-five degrees and eighty-five degrees.

52. An electronic component, comprising:
micro-electric insulating structures, comprising:
trenches in a substrate with inclined walls having a substantially constant slope and with rounded top corners; and
a dielectric material disposed in the trenches; and
active micro-electric structures between the micro-electric insulating structures.

53. An integrated circuit, comprising:
electronic components, comprising:
micro-electric insulating structures, comprising:
trenches in a substrate with inclined walls having a substantially constant slope and with rounded top corners; and
a dielectric material disposed in the trenches; and
active micro-electric structures between the micro-electric insulating structures; and
electronic connectors between the electronic components.
